(19) United States
(12) Patent Application Publication
(10) Pub. No.: US 2007/0075219 A1
(43) Pub. Date: Apr. 5, 2007

(54) ACTIVE PIXEL SENSOR CIRCUIT AND RELATED CONTROLLING METHOD

(76) Inventor: Chih-Cheng Hsieh, Hsin-Chu Hsien (TW)

Correspondence Address: NORTH AMERICA INTELLECTUAL PROPERTY CORPORATION, P.O. BOX 506, MERRIFIELD, VA, 22116, US

(21) Appl. No.: 11/420,007

(22) Filed: May 24, 2006

(30) Foreign Application Priority Data
Sep. 30, 2005 (TW) 094134235

(51) Int. Cl. H01L 27/00

(52) U.S. Cl. 250/208.1

(57) ABSTRACT

An active pixel sensor circuit includes a sensor, a reset transistor, a source-follower transistor, and a row-selector transistor. A gate of the row-selector transistor is electrically connected to a drain of the reset transistor. A method for controlling the active pixel sensor circuit includes turning on the row-selector transistor and the reset transistor when resetting the sensor, and turning on the row-selector transistor and the reset transistor when reading a reset signal. In this way, parasitic capacitance at a gate of the source-follower transistor when resetting the sensor is the same as when reading the reset signal.

### BACKGROUND OF THE INVENTION

1. Field of the Invention

The present invention relates to an active pixel sensor circuit and related controlling method, and more particularly, to an active pixel sensor of a gate of a row-selector transistor coupled to a drain of a reset transistor and related controlling method.

2. Description of the Prior Art

Active pixel sensor circuits with three or more transistors (3T, 4T, etc) are commonly available. Please refer to FIG. 1, which is a diagram of a 4T active pixel sensor circuit 1 according to the prior art. The 4T active pixel sensor circuit 1 comprises a sensor 10 for receiving light, a transfer transistor 18 for controlling transfer of photoelectric charge of the sensor 10, a reset transistor 12 for resetting the sensor 10, a source-follower transistor 14, and a row-selector transistor 16 for controlling reading of a light signal and a reset signal. Please refer to FIG. 2, which is a diagram of a 3T active pixel sensor circuit 2 according to the prior art. The 3T active pixel sensor circuit 2 does not comprise the transfer transistor 18, and thereby the source-follower transistor 14 and the row-selector transistor 16 control transfer of photoelectric charge of the sensor 10 simultaneously. Additionally, the sequences of reading signals for the 3T active pixel sensor circuit 2 and the 4T active pixel sensor circuit 1 are different. In the 3T active pixel sensor circuit 2, a light signal is read and then a reset signal is read. On the contrary, in the 4T active pixel sensor circuit 1, a reset signal is read and then a light signal is read.

There are two reset modes in the prior art. One is soft reset, and the other is hard reset. Definitions of the two modes are illustrated in following equations.
Soft reset:VRST>RST−VT
Hard reset:VRST<RST−VT

wherein VRST represents the voltage at the drain of the reset transistor 12, RST represents the voltage at the gate of the reset transistor 12, and VT represents a threshold voltage.

Take the 4T active pixel sensor circuit 1 of FIG. 1 for example. Please refer to FIG. 3, which is a timing diagram of controlling the 4T active pixel sensor circuit 1 of FIG. 1. When a NOV signal is high, the reset signal and the light signal of the active pixel sensor circuit 1 are read. An SHR signal and an SHS signal are controlling signals of the reset signal and the light signal, respectively. If the active pixel sensor circuit 1 undergoes a hard reset, a VDDAY signal stays at high. In a soft reset, when the reset transistor 12 is turned on, a VDDAY_rst signal has to drop to low and then to rise to high. In the reset mode and when reading signals, the reset transistor 12 is totally turned on twice: once when resetting the sensor 10 and another time when reading the reset signal. Therefore, the VDDAY_rst signal has to drop to low, then to rise to high correspondingly.

During the reset mode for the sensor 10 and the exposure process, an Rsel signal for controlling the row-selector transistor 16 stays at low, and rises to high until the preparation for reading the reset signal. After reading the light signal, Rsel signal drops to low.

When resetting the sensor 10, an Rrst signal for controlling the reset transistor 12 and a TG signal for controlling the transfer transistor 18 are at high. When reading the reset signal, the Rrst signal rises to high. When reading the light signal, the TG signal rises to high for transferring photoelectric charge of the sensor 10.

During the reset mode, a parasitic capacitance environment at the gate of the source-follower transistor 14 exists because the reset transistor 12 is turned on while the row-selector transistor 16 is turned off. The exposure process is executed after the reset mode. That is, when TG signal drops to low, the exposure process starts. The active pixel sensor circuit 1 has no ability to record the voltage at the gate of the source-follower transistor 14 before the exposure process starts. Thus, before reading the light signal, a reset signal must be generated and read for the initial voltage (reference voltage) of the light signal. However, as shown in FIG. 3, when reading the reset signal, a parasitic capacitance environment at the gate of the source-follower transistor 14 exists because the reset transistor 12 and the row-selector transistor 16 are both turned on, which is different from that of the reset mode. Therefore, the initial voltage of the light signal is not precisely generated, resulting in a loss of precision in captured images.

In addition, in order to reduce the quality of physical lines of controlling signals, other circuits are designed, such as a 4T active pixel sensor circuit 4 of FIG. 4 and a 3T active pixel sensor circuit 5 of FIG. 5, where the drain of the reset transistor 12 and the drain of the source-follower transistor 14 are coupled together and are controlled by a single signal. As another example, a 4T active pixel sensor circuit 6 of FIG. 6 and a 3T active pixel sensor circuit 7 of FIG. 7, where both active pixel sensor circuits undergo a soft reset. In order to control such active pixel sensor circuits more easily, the VDDAY_rst line is changed to be horizontal.

Among the circuits mentioned above, there are three vertical lines (VDDAY, VDDA, and PXO) and three horizontal lines (Rrst, Rsel, and TG) in the 4T active pixel sensor circuit 1 of FIG. 1; three vertical lines (VDDAY, VDDA, and PXO) and two horizontal lines (Rrst and Rsel) in the 3T active pixel sensor circuit 2 of FIG. 2; two vertical lines (VDDAY, and PXO) and three horizontal lines (Rrst, Rsel, and TG) in the 4T active pixel sensor circuit 4 of FIG. 4; two vertical lines (VDDAY and PXO) and two horizontal lines (Rrst and Rsel) in the 3T active pixel sensor circuit 5 of FIG. 5; two vertical lines (VDDAY and PXO) and four horizontal lines (Rrst, Rsel, VDDAY_rst, and TG) in the 4T active pixel sensor circuit 6 of FIG. 6; and two vertical lines (VDDA and PXO) and three horizontal lines (Rrst, Rsel, and VDDAY_rst) in the 3T active pixel sensor circuit 7 of FIG. 7.

No matter which circuit is used, 3T active pixel sensor circuit requires at least four lines, and 4T active pixel sensor circuit requires at least five lines. However, the number of lines affects the area of capturing light for the sensor 1 0, and influences a fill factor correspondingly.

### SUMMARY OF THE INVENTION

The claimed invention discloses an active pixel sensor circuit. The active pixel sensor circuit comprises a sensor, a reset transistor, a source-follower transistor, and a row-selector transistor. A source of the reset transistor is coupled to a sensor. A gate of the source-follower transistor is coupled to the source of the reset transistor. The row-selector includes a gate coupled to a drain of the reset transistor, a drain coupled to a source of the source-follower transistor, and a source coupled to a pixel line.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a 4T active pixel sensor circuit according to the prior art.

FIG. 2 is a diagram of a 3T active pixel sensor circuit according to the prior art.

FIG. 3 is a timing diagram of controlling the 4T active pixel sensor circuit of FIG. 1.

FIG. 4 to FIG. 7 show other active pixel sensor circuits according to the prior art.

FIG. 8 to FIG. 11 show 4T and 3T active pixel sensor circuits according to the present invention.

FIG. 12 is a timing diagram of controlling the 4T active pixel sensor circuit of FIG. 10.

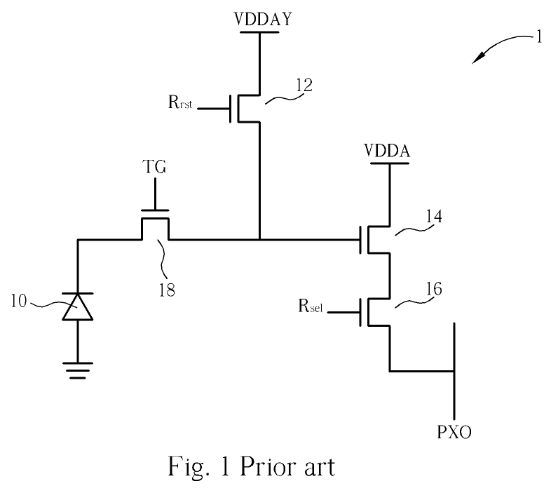

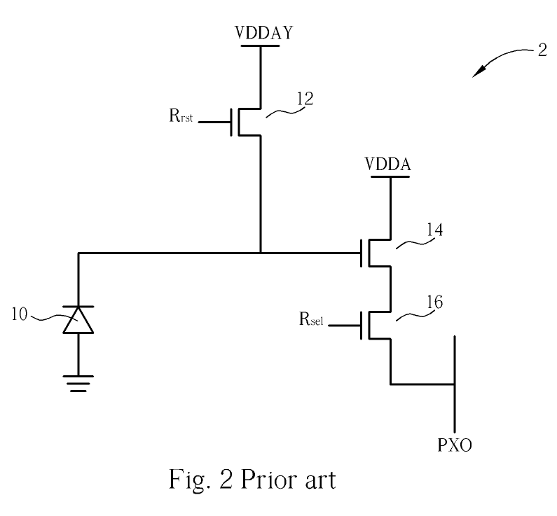

### DETAILED DESCRIPTION

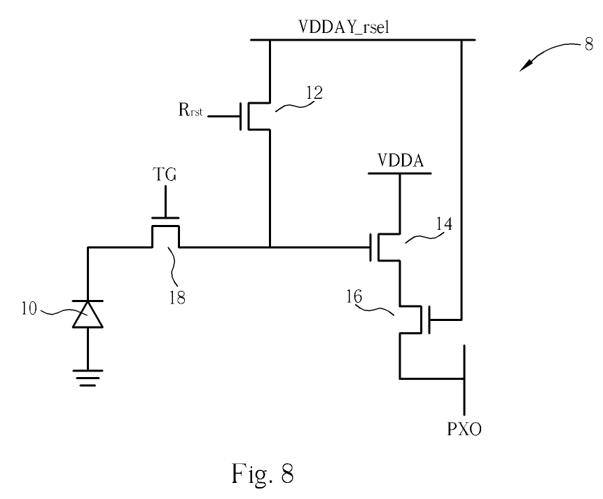

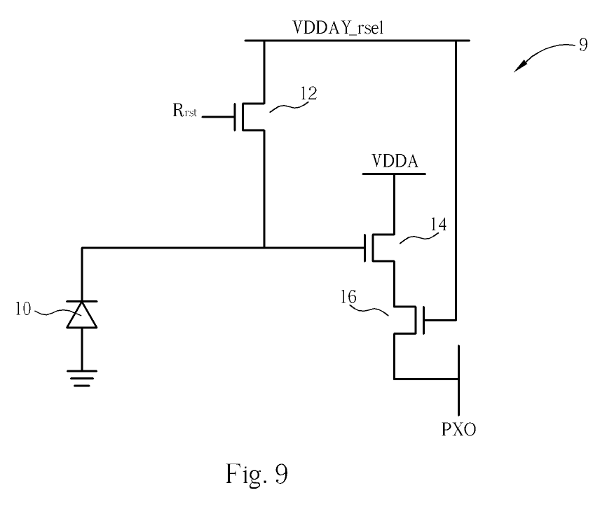

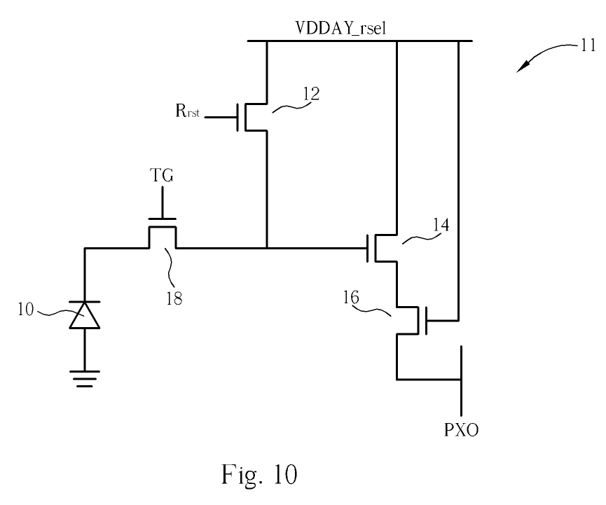

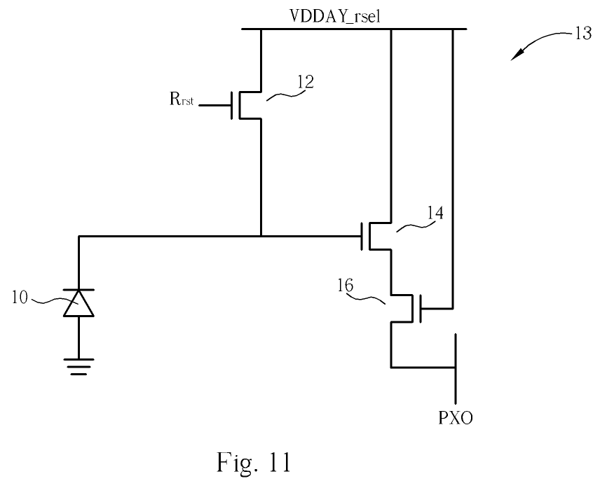

Please refer to FIG. 8 to FIG. 11, which show 4T and 3T active pixel sensor circuits 8, 9, 11 and 13 according to the present invention. The present invention connects the gate of the row-selector transistor 16 and the drain of the reset transistor 12, as shown in FIG. 8 and 9. It is also practicable to connect the drain of the source-follower transistor 14, the gate of the row-selector transistor 16, and the drain of the reset transistor 12 together, as shown in FIG. 10 and 11.

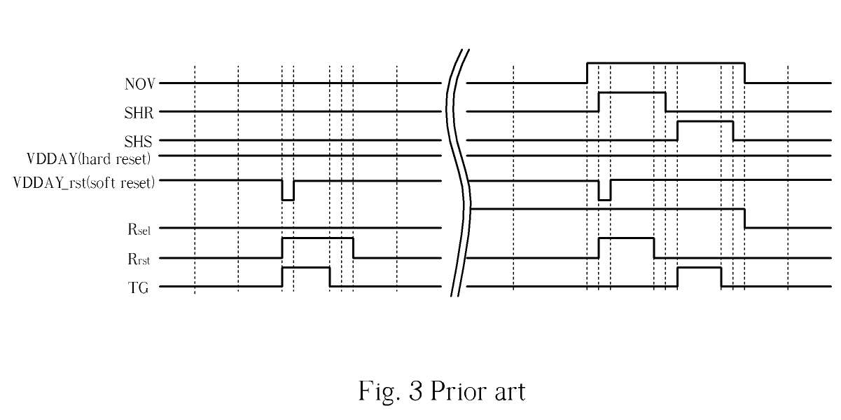

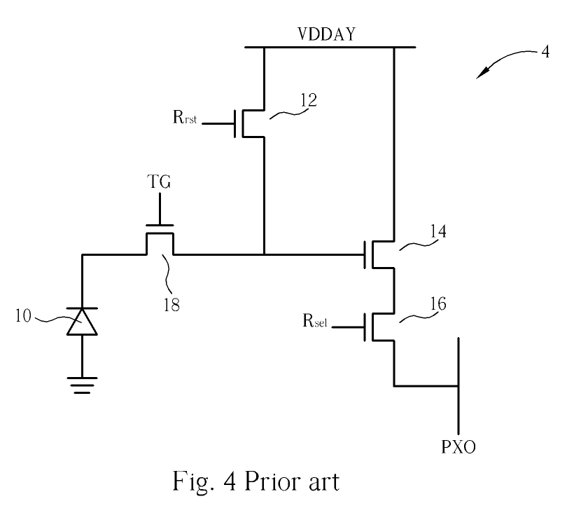

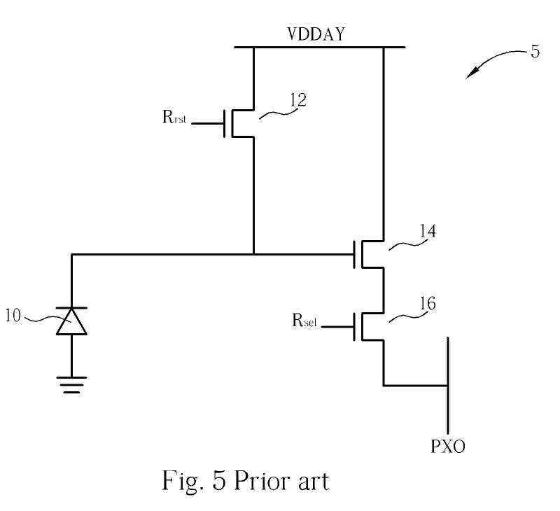

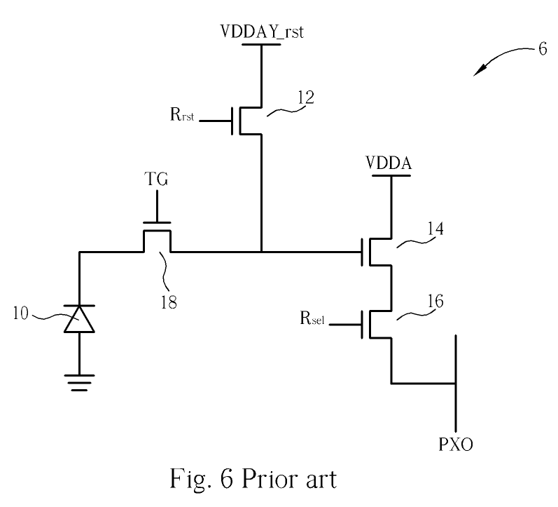

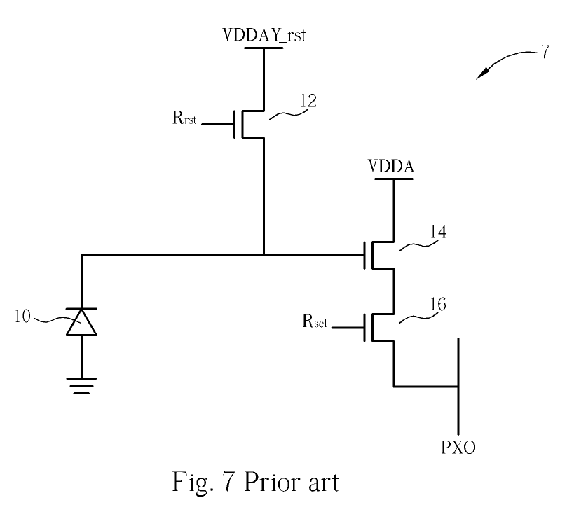

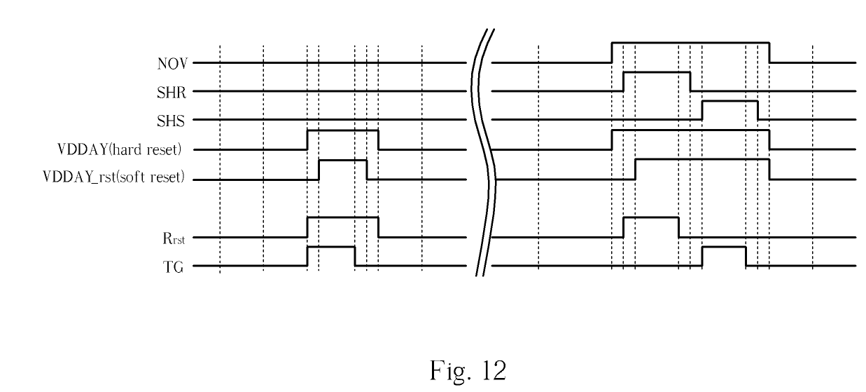

Take the 4T active pixel sensor circuit 11 of FIG. 10 for example to illustrate the timing of the active pixel sensor circuits of the present invention. Please refer to FIG. 12, which is a timing diagram of controlling the 4T active pixel sensor circuit 11 of FIG. 10. NOV, SHR, SHS, Rrst and TG signals are the same as those in FIG. 3, and further description of these is thereby omitted.

Since the drain of the source-follower transistor 14, the gate of the row-selector transistor 16 and the drain of the reset transistor 12 are coupled together, there is a little change of the timing of controlling signals. Suppose that the active pixel sensor circuit 11 undergoes a hard reset. During the reset mode, the VDDAY signal rises from low to high and the row-selector transistor 16 is also turned on. Although he row-selector transistor 16 is turned on, signals are not read because the NOV, SHR and SHS signals are low.

In soft reset, when the reset transistor 12 is turned on, the VDDAY_rst signal must stay at low for a while and then rise to high. Therefore, in FIG. 12, when the Rrst signal rises to high, the VDDAY_rst signal starts low and then rises to high.

As mentioned above, no matter whether the active pixel sensor circuit undergoes a hard or soft reset, during the reset mode and before the exposure process starts, a parasitic capacitance environment at the gate of the source-follower transistor 14 exists because the reset transistor 12 and the row-selector transistor 16 are both turned on.

When reading the reset signal, the hard reset VDDAY signal rises to high immediately when the NOV signal rises to high. This results in turning on the row-selector transistor 16. In soft reset, when reading the reset signal, the VDDAY_rst signal stays low and then rises to high. The VDDAY_rst signal rising to high causes the row-selector transistor 16 to be turned on. Therefore, reading the reset signal in soft and hard reset results in a parasitic capacitance environment at the gate of the source-follower transistor 14 of the reset transistor 12 and the row-selector transistor 16 both being turned on, which is identical to that in the reset mode. The circuit and controlling method of the present invention can resolve the problem of the parasitic capacitance environment when reading the reset signal differing from that when resetting the sensor 10.

Additionally, if the active pixel sensor circuit of the present invention is implemented, the 4T active pixel sensor circuit 11 just requires a vertical line (PXO) and three horizontal lines (Rrst, VDDAY_rsel, and TG) for a total of four controlling lines. The 4T active pixel sensor circuit 8 has more vertical lines (VDDA) than the 4T active pixel sensor circuit 11 does. The 3T active pixel sensor circuit 13 just requires a vertical line (PXO) and two horizontal lines (Rrst and VDDAY_rsel) for a total of three controlling lines. The 3T active pixel sensor circuit 9 has more vertical lines (VDDA) than the 3T active pixel sensor circuit 12 does.

In the 3T active pixel sensor circuit of the present invention, at most four controlling lines are required. The 4T active pixel sensor circuit requires five lines at most. Thus, controlling lines can be reduced to increase the area of capturing light for the sensor 10 and to increase a fill factor correspondingly.

In the 4T active pixel sensor circuits 8, 11 and the 3T active pixel sensor circuits 9, 13, the sensor 10 is a photodiode, a pinned diode, or a photogate. The reset transistor 12, the source-follower transistor 14, the row-selector transistor 16, and the transfer transistor 18 are NMOS or PMOS transistors.

The present invention couples the gate of the row-selector transistor with the drain of the reset transistor so that the number of controlling lines can be reduced and a fill factor can be increased. In the controlling timing of the present invention, the reset transistor and the row-selector transistor are both turned on in the reset mode, and are both also turned on when reading the reset signal. Therefore, parasitic capacitance at the gate of the source-follower transistor when resetting the sensor is the same as when reading the reset signal. This can generate a more precise voltage at the gate of the source-follower transistor for the initial voltage of the light signal, and can thereby improve imaging quality.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An active pixel sensor circuit comprising:
a sensor for receiving light;
a reset transistor having a source coupled to the sensor for resetting the sensor;
a source-follower transistor having a gate coupled to the source of the reset transistor; and
a row-selector transistor having a gate coupled to a drain of the reset transistor, a drain coupled to a source of the source-follower transistor, and a source coupled to a pixel line.

2. The active pixel sensor circuit of claim 1, wherein the source-follower transistor has a drain coupled to the drain of the reset transistor.

3. The active pixel sensor circuit of claim 1, wherein the sensor comprises a photodiode, a pinned diode, or a photogate.

4. The active pixel sensor circuit of claim 1 further comprising a transfer transistor coupled between the sensor and the source of the reset transistor for controlling transfer of photoelectric charge of the sensor.

5. The active pixel sensor circuit of claim 4, wherein the transfer transistor is an NMOS transistor having a source coupled to the sensor and a drain coupled to the source of the reset transistor.

6. The active pixel sensor circuit of claim 5, wherein the reset transistor, the source-follower transistor, and the row-selector transistor are NMOS transistors.

7. A method for controlling an active pixel sensor circuit, the method comprising:
turning on a reset transistor coupled to a sensor and a row-selector transistor having a drain coupled to a source of a source-follower transistor when resetting the sensor, the source-follower transistor having a gate coupled to a source of the reset transistor;
turning off the reset transistor and the row-selector transistor when the sensor is at an initial exposure time;
turning on the row-selector transistor when reading a light signal received by the sensor; and
turning on the reset transistor when reading a reset signal;
wherein parasitic capacitance at the gate of the source-follower transistor when resetting the sensor is the same as when reading the reset signal.

8. A method for controlling an active pixel sensor circuit, the method comprising:
turning on a reset transistor coupled to a sensor, a row-selector transistor having a drain coupled to a source of a source-follower transistor, and a transfer transistor coupled between the reset transistor and the sensor when resetting the sensor, the source-follower transistor having a gate coupled to a source of the reset transistor;
turning off the reset transistor, the row-selector transistor, and the transfer transistor when the sensor is at an initial exposure time;
turning on the reset transistor and the row-selector transistor when reading a reset signal; and
turning off the reset transistor and turning on the transfer transistor when reading a light signal received by the sensor;
wherein parasitic capacitance at the gate of the source-follower transistor when resetting the sensor is the same as when reading the reset signal.
